(19) United States
(12) Patent Application Publication
(10) Pub. No.: US 2001/0014519 A1
(43) Pub. Date: Aug. 16, 2001

(54) NOVEL METHOD FOR THE FORMATION OF VARIOUS OXIDE THICKNESSES ON A NITRIDE

(76) Inventor: ROBERT B. OGLE, SAN JOSE, CA (US)

Correspondence Address: LARIVIERE, GRUBMAN & PAYNE, LLP, 1 LOWER RAGSDALE, BLDG. 1, SUITE 130, P.O. BOX 3140, MONTEREY, CA, 93942, US

(21) Appl. No.: 09/057,419

(22) Filed: Apr. 8, 1998

(51) Int. Cl. H01L 21/3205; H01L 21/4763; H01L 21/31; H01L 21/469

(52) U.S. Cl. 438/585; 438/591

(57) ABSTRACT

The present invention provides a fabrication process for fabricating a MOS substrate structure having a predetermined thickness of thermally grown oxide on top of a silicon nitride film. A poly-crystalline or amorphous silicon film is deposited onto the nitride film at a desirable fabrication stage requiring a robust oxide layer. The thickness of the silicon film is determined by the desired thickness of the thermal oxide according to pre-determined oxidation rate characteristics between the silicon film material and the oxidant in dry oxygen, or steam form. Typically, the thickness of the oxide grown is approximately 1.75 to 2.00 times the thickness of the silicon film. Care must be taken during subsequent processing to prevent excessive oxide removal. The present invention allows the use of cleaning solutions that are tailored to reduce etching of silicon, which is an easier task than reduce oxide etching. The oxidized silicon film is more robust against etching during HF and SCI or APM cleaning. There is less oxide film loss during cleaning, resulting in more reproducible results. The oxidized silicon film may be used to reduce loss of isolation or field oxide during subsequent processes by exercising the reduced etching rate of hydrofluoric acid (HF) or SCI mixtures.

### TECHNICAL FIELD

The present invention relates to integrated circuits and fabrication techniques for forming oxide layers on the integrated circuit's substrate. More particularly, the present invention relates to integrated circuits and fabrication techniques for forming oxide barriers on silicon nitride film. Even more particularly, the present invention relates to integrated circuits and fabrication techniques for thermally forming oxide barriers on silicon nitride film.

### BACKGROUND OF THE INVENTION

MOS technology requires a thin layer of dielectric material grown in the gate region to control induction of electric charge in the gate region to cause the flow of current through the device. Aside from the dielectric function of the thin layer, the layer also serves as a doping barrier, or as a contamination barrier. Typically, the thin layer is a silicon dioxide layer, or a silicon nitride layer which is formed on the silicon substrate. In applications where the thin gate oxide layer is in the 100 Å (or less) range, the silicon dioxide film is not suitable. Thermally grown silicon nitride (Si₃N₄) is used as an alternative in the 100 Å range due to the Si₃N₄ material being denser than silicon dioxide. The silicon nitride film is formed by the exposure of the silicon substrate to ammonia (NH₃) between 950° C. and 1200° C. Protective barriers are required after formation of MOS devices. These barriers are produced by existing technology using a long steam oxidation process that grows about 35 Å of oxide over the silicon nitride. The amount of oxide may be dependent upon the stoichiometry of the nitride and the oxidation conditions. The thickness of the oxide over the nitride produced by this prior art method are seen as a limitation and have questionable protection effectiveness. Further, the use of cleaning solutions that are tailored to reduce oxide etching must be used and limits the use during cleaning of HF, and SCI, which is an ammonia peroxide mixture commercially known as APM. Thus, a need is seen to exist for an oxide forming process in the semiconductor industry for forming an oxide layer over a nitride layer that overcomes the foregoing disadvantages.

Thus, a primary object of the present invention is to provide a semiconductor fabrication process for forming an oxide barrier over a silicon nitride film whose thickness can be controlled and that allows the use of cleaning solutions, such as HF, SCI or APM that are tailored to reduce etching of silicon.

A related object of the present invention is to provide a semiconductor apparatus having an oxide barrier over a silicon nitride film formed in accordance with the above primary object.

### BRIEF SUMMARY OF THE INVENTION

Accordingly, the foregoing objects are accomplished by providing a fabrication process whereby a poly-crystalline or amorphous silicon film is deposited onto a nitride film at a desirable fabrication stage requiring a robust oxide layer. The thickness of the silicon film is determined by the desired thickness of the thermal oxide according to pre-determined oxidation rate characteristics between the silicon film material and the oxidant in dry oxygen, or steam form. Typically, the thickness of the oxide grown is approximately 1.75 to 2.00 times the thickness of the silicon film. The oxide layer thickness can thus be varied by a thermally grown oxide on top of a silicon nitride film. In a dry oxygen environment and according to known silicon/dry oxygen oxidation rate characteristics, exposure of a deposited silicon layer, having a thickness of 100 Å to 114 Å, for at least one hour duration, at a temperature ranging from 900° C. to 1300° C., results in growing a silicon dioxide layer having a thickness of at least 200 Å. Similarly, in a steam, oxygen-containing environment, and according to known silicon/steam, oxygen-containing oxidation rate characteristics, exposure of a deposited silicon layer, having a thickness of 1000 Å to 1140 Å, for at least one hour duration, at a temperature ranging from 800° C. to 1300° C., results in growing a silicon dioxide layer having a thickness of at least 2000 Å. Although care must be taken during subsequent processing to prevent excessive oxide removal, the present invention allows the use of cleaning solutions that are tailored to reduce etching of silicon, which is an easier task than reducing oxide etching. The silicon film may be used to reduce loss of isolation or field oxide during subsequent processes by exercising the reduced etching rate of hydrofluoric acid (HF) or SCI mixtures.

Although, preferably the process is used to protect a silicon nitride layer, other exposed surfaces on the substrate, such as field oxide surfaces, silicon substrate surfaces, or epitaxial silicon surfaces may be processed in accordance with the present invention.

Other features of the present invention are disclosed or apparent in the section entitled: “DETAILED DESCRIPTION OF THE INVENTION”.

### BRIEF DESCRIPTION OF DRAWINGS

For fuller understanding of the present invention, reference is made to the accompanying drawing in the following Detailed Description of the Invention. In the drawings:

FIG. 1 is a cross-section of a semiconductor substrate shown at a fabrication stage having various gate regions formed to a ready state for being processed in accordance with the present invention.

FIG. 2 is a cross-section of the semiconductor substrate depicted in FIG. 1 after undergoing fabrication steps that includes deposition of a silicon film over a silicon nitride layer in accordance with the present invention.

FIG. 3 shows the results of an exemplary step of masking and etching undesired regions of silicon and silicon nitride on the substrate structure depicted in FIG. 2.

FIG. 4 shows the substrate structure depicted in FIG. 3 after a fabrication step of thermally growing a layer of silicon dioxide over the silicon film in accordance with the present invention.

Reference numbers refer to the same or equivalent parts of the present invention throughout the several figures of the drawing.

### DETAILED DESCRIPTION OF THE INVENTION

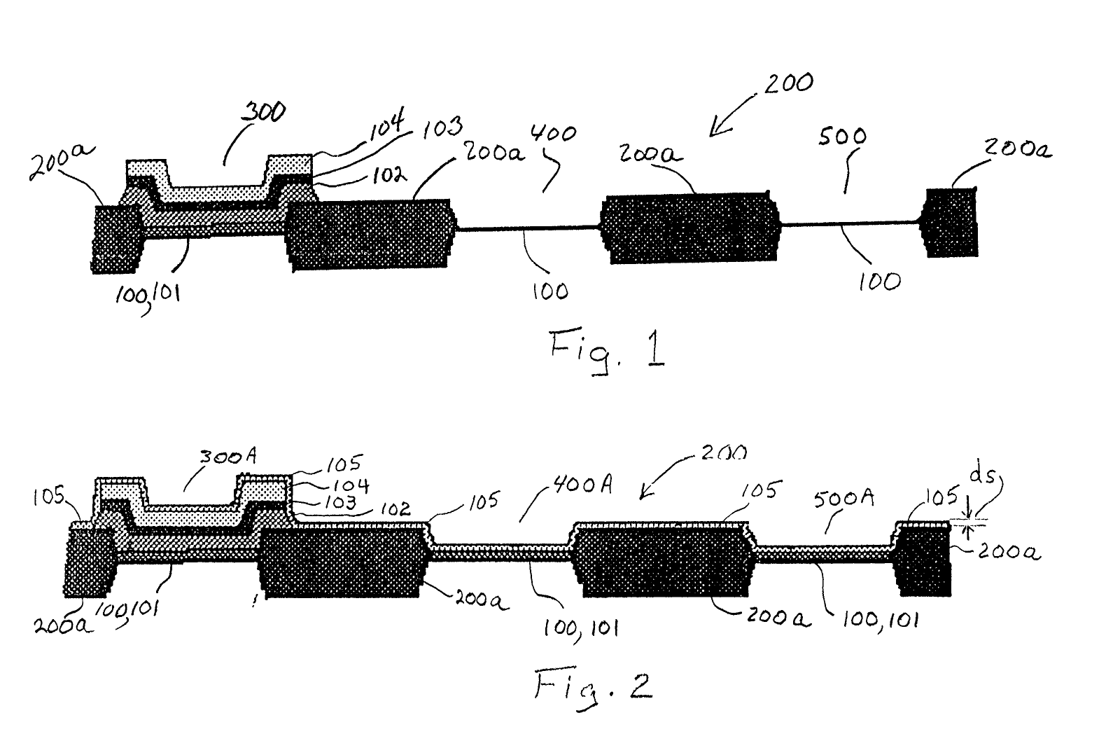

FIG. 1 is a cross-section of a semiconductor substrate 200 having silicon surface 100 and MOS gate regions 300, 400, and 500 at an arbitrary fabrication stage for forming a silicon dioxide layer in accordance with the present invention. Gate regions 300, 400 and 500 are isolated one from the other by an isolation region 200a. As illustrated, gate region 300 comprises a stack including a silicon dioxide layer 101 grown over silicon substrate surface 100, a first poly silicon layer 102, a second silicon dioxide layer 103 and a field silicon nitride layer 104. By example, silicon dioxide layer 101 may be formed by the exposure of the silicon substrate 100 to an oxygen-containing atmosphere and heating the substrate to a temperature in the range of 850° C. to 950° C. for approximately thirty (30) minutes. After patterning and etching steps, first polysilicon layer 102 is deposited over silicon dioxide layer 101. Second silicon dioxide layer 103 may be grown as described above in forming layer 101. Silicon nitride layer 104 is formed over second silicon dioxide layer 103. Silicon nitride layer 104 and is at a stage where an additional protective isolation layer would be desirable. Gate regions 400 and 500, as illustrated in FIG. 1, have silicon surface 100 exposed and are also at a stage of fabrication where a protective isolation layer would also be desirable.

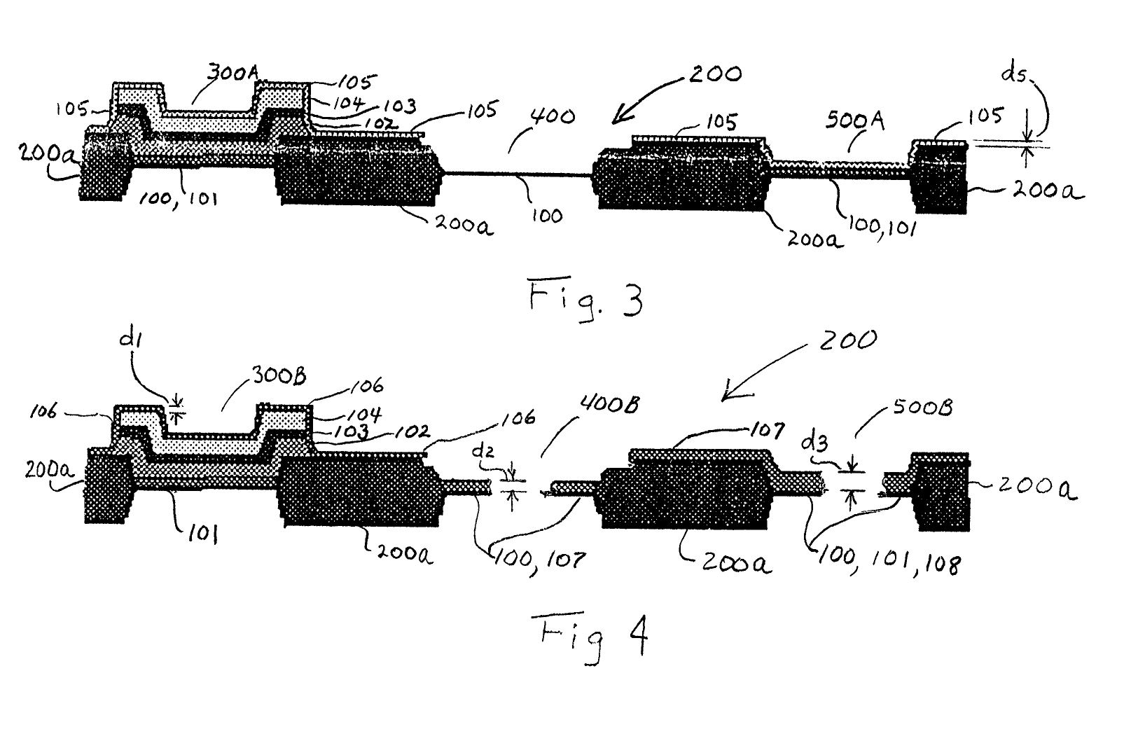

FIG. 2 shows a cross-section of the semiconductor substrate depicted in FIG. 1 after undergoing fabrication steps that includes deposition of a silicon film 105 over a silicon dioxide layer 101 in regions 400 and 500 forming regions 400A and 500A and over the silicon nitride layer 104 in region 300 forming region 300A. By example, silicon dioxide layer 101 is formed in regions 400 and 500 over silicon substrate surface 100 prior to deposition of silicon film 105, by exposure of the silicon substrate 100 to an oxygen-containing atmosphere and heating the substrate to a temperature in the range of 850° C. to 950° C. for approximately thirty (30) minutes. Silicon film 105 comprises a poly-crystalline or amorphous silicon film material deposited onto silicon dioxide film 101 in regions 400A and 500A and over silicon nitride layer 104 in region 300A. The deposition of silicon film 105 comprises a process of depositing silicon by low pressure chemical vapor deposition, LPCVD. The thickness of film 105 ds is determined by the desired final thickness d1, d2 and d3 of the thermal oxide layers 106, 107, and 108, respectively, to be formed, see generally FIG. 4. In the preferred embodiment of the invention, the thickness of a thermal oxide layer is on the order of 1.75 to 2.0 times the thickness of the silicon film deposited. FIG. 3 shows the results of an exemplary step of masking and etching undesired regions of silicon, or silicon dioxide on the substrate structure. As illustrated, region 400A has been etched back to a state where only the silicon substrate 100 remains, i.e. back to region 400 state, depicted in FIG. 1. As illustrated in FIG. 4, after deposition and necessary patterning to remove the undesired regions of silicon and silicon dioxide the wafer 200 is subjected to an ambient that oxidizes silicon film 105 to produce silicon oxide layers 106. 107, 108. By example, oxide layers 106, 107 and 108 are formed by placing substrate 200 in an oxygen-containing atmosphere and heating the substrate to a temperature in the range of 850° C. to 950° C. for approximately thirty (30) minutes. FIG. 4 shows region 300B with a thermal silicon dioxide layer 106 formed to a thickness d1 after exposure of silicon film 105 to the oxygen-containing atmosphere. Here silicon film 105 was deposited over the silicon nitride layer 104, which after growing the thermal oxide layer 106 on silicon film 105 provides region 300B with the desired passivation protection. Similarly, FIG. 4 shows region 400B with a thermal silicon dioxide layer 107 formed to a thickness d2 after exposure of silicon surface 100 to a similar oxygen-containing atmosphere used to grow silicon dioxide layer 106. Here, silicon film 105 had been previously etched which exposed the region 400 and silicon surface 100, which after exposure to the oxygen-containing atmosphere formed thermal silicon dioxide layer 107, and which also provides region 400B with the desired passivation protection. As illustrated in FIG. 3, region 500A has been process with a silicon film 105 deposited over a silicon dioxide layer 101. After exposure to the oxygen-containing atmosphere as discussed above, and as depicted in FIG. 4, region 500B is formed by forming silicon dioxide layer 108 to a thickness d3. Here silicon dioxide layer 108 is formed over the silicon film 105. The thickness d3 is on the order of 1.75 to 2.00 times the thickness ds of silicon film 105.

The present invention has been particularly shown and described with respect to a certain preferred embodiment and features thereof. However, it should be readily apparent to those of ordinary skill in the art that various changes and modifications in form, semiconductor material, material conductivity type, i.e. N-type, or P-type, and detail may be made without departing from the spirit and scope of the inventions as set forth in the appended claims. The inventions illustratively disclosed herein may be practiced without any element which is not specifically disclosed herein.

What is claimed is:

1. A method for forming a passivation layer having a controlled thickness in a MOS semiconductor apparatus, said method comprising the steps of:
(a) providing a semiconductor substrate;
(b) providing at least one region on said substrate member having a silicon nitride passivation layer;
(c) depositing a silicon material over said silicon nitride passivation layer, said silicon material forming a silicon layer over said silicon nitride layer and having a predetermined first thickness; and
(d) forming a silicon dioxide layer by exposing said silicon layer to an oxidant, said silicon dioxide layer having a second thickness proportionately related to said first thickness by a predetermined ratio controllable by oxidation rate characteristics between said silicon material and said oxidant.

2. A method for forming a passivation layer having a controlled thickness as described in claim 1, wherein:
said step (c) comprises providing said silicon material as a poly-crystalline silicon material; and said method further comprises a step (e) of cleaning said MOS semiconductor apparatus using a cleaning solution selected from the group consisting of HF, SCI and APM.

3. A method for forming a passivation layer having a controlled thickness as described in claim 1, wherein:
said step (c) comprises providing said silicon material as an amorphous silicon material; and said method further comprises a step (e) of cleaning said MOS semiconductor apparatus using a cleaning solution selected from the group consisting of HF, SCI and APM.

4. A method for forming a passivation layer having a controlled thickness as described in claim 1, wherein:
said forming step (d) comprises exposing said silicon layer to a dry oxygen environment for at least one hour duration at a temperature ranging from 900° C. to 1300° C., and thereby growing a silicon dioxide layer such that said second thickness is at least 200 Å.

5. A method for forming a passivation layer having a controlled thickness as described in claim 4, wherein:
said first thickness being proportionately related to said second thickness by a (0.50 to 0.57):1 ratio, such that said first thickness is 100 Å to 114 Å.

6. A method for forming a passivation layer having a controlled thickness as described in claim 1, wherein:
said forming step (d) comprises exposing said silicon layer to a steam, oxygen-containing environment for at least one hour duration at a temperature ranging from 800° C. to 1300° C., and thereby growing a silicon dioxide layer such that said second thickness is at least 2000 Å.

7. A method for forming a passivation layer having a controlled thickness as described in claim 6, wherein:
said first thickness being proportionately related to said second thickness by a (0.50 to 0.57):1 ratio, such that said first thickness is 1000 Å to 1140 Å.

8. A method for forming a passivation layer having a controlled thickness as described in claim 1, wherein:
said second thickness being proportionately related to said first thickness by a (1.75 to 2.00):1.00 ratio; and said method further comprises a step (e) of cleaning said MOS semiconductor apparatus using a cleaning solution selected from the group consisting of HF, SCI, and APM.

9. A method for forming an oxide layer over nitride in a MOS semiconductor apparatus, said method comprising the steps of:
(a) providing a semiconductor substrate;
(b) providing at least one region on said substrate member having a silicon nitride passivation layer;
(c) depositing a silicon material over said silicon nitride passivation layer, said silicon material forming a silicon layer over said silicon nitride layer and having a predetermined first thickness; and
(d) forming a silicon dioxide layer by exposing said silicon layer to a steam, oxygen-containing environment, said silicon dioxide layer having a second thickness proportionately related to said first thickness by a predetermined ratio controllable by a pre-determined oxidation rate characteristics between said silicon material and oxygen in steam form.

10. A method for forming an oxide layer over nitride as described in claim 9, wherein:
said step (c) comprises providing said silicon material as a poly-crystalline silicon material; and
said forming step (d) comprises exposing said silicon layer to a steam, oxygen-containing environment for at least one hour duration at a temperature ranging from 800° C. to 1300° C., and growing a silicon dioxide layer such that said second thickness is at least 2000 Å.

11. A method for forming an oxide layer over nitride as described in claim 10, wherein:
said first thickness being proportionately related to said second thickness by a (0.50 to 0.57):1 ratio, such that said first thickness is 1000 Å to 1140 Å.

12. A method for forming an oxide layer over nitride as described in claim 9, wherein:
said step (c) comprises providing said silicon material as an amorphous silicon material; and
said forming step (d) comprises exposing said silicon layer to a steam, oxygen-containing environment for at least one hour duration at a temperature ranging from 800° C. to 1300° C., and thereby growing a silicon dioxide layer such that said second thickness is at least 2000 Å.

13. A method for forming an oxide layer over nitride as described in claim 12, wherein:
said first thickness being proportionately related to said second thickness by a (0.50 to 0.57):1 ratio, such that said first thickness is 1000 Å to 1140 Å.

14. A method for forming an oxide layer over nitride in a MOS semiconductor apparatus, said method comprising the steps of:
(a) providing a semiconductor substrate;
(b) providing at least one region on said substrate member having a silicon nitride passivation layer;
(c) depositing a silicon material over said silicon nitride passivation layer, said silicon material forming a silicon layer over said silicon nitride layer having a predetermined first thickness; and
(d) forming a silicon dioxide layer by exposing said silicon layer to a dry oxygen environment, said silicon dioxide layer having a second thickness proportionately related to said first thickness by a predetermined ratio controllable by a predetermined oxidation rate characteristics between said silicon material and dry oxygen.

15. A method for forming an oxide layer over nitride as described in claim 14, wherein:
said step (c) comprises providing said silicon material as a poly-crystalline silicon material; and
said forming step (d) comprises exposing said silicon layer to a dry oxygen environment for at least one hour duration at a temperature ranging from 900° C. to 1300° C., and thereby growing a silicon dioxide layer such that said second thickness is at least 200 Å.

16. A method for forming an oxide layer over nitride as described in claim 15, wherein:
said first thickness being proportionately related to said second thickness by a (0.50 to 0.57):1 ratio, such that said first thickness is 100 Å to 114 Å.

17. A method for forming an oxide layer over nitride as described in claim 14, wherein:
said step (c) comprises providing said silicon material as an amorphous silicon material; and
said forming step (d) comprises exposing said silicon layer to a dry oxygen environment for at least one hour duration at a temperature ranging from 900° C. to 1300° C., and thereby growing a silicon dioxide layer such that said second thickness is at least 200 Å.

18. A method for forming an oxide layer over nitride as described in claim 17, wherein:
said first thickness being proportionately related to said second thickness by a (0.50 to 0.57):1 ratio, such that said first thickness is 100 Å to 114 Å.

19. A MOS semiconductor apparatus having an oxide layer over a nitride layer, said apparatus comprising:
a semiconductor substrate;
at least one region on said substrate member having a silicon nitride passivation layer;
a silicon material deposited over said silicon nitride passivation layer, said silicon material forming a silicon layer over said silicon nitride layer having a predetermined first thickness; and
a silicon dioxide layer grown over said silicon layer, said silicon dioxide layer having a predetermined second thickness formed by exposing said silicon layer to a steam, oxygen-containing environment, said second thickness being proportionately related to said first thickness by a predetermined ratio controllable by a pre-determined oxidation rate characteristics between said silicon material and oxygen in steam form.

20. A MOS semiconductor apparatus having an oxide layer over a nitride layer, said apparatus comprising:
a semiconductor substrate;
at least one region on said substrate member having a silicon nitride passivation layer;
a silicon material deposited over said silicon nitride passivation layer, said silicon material forming a silicon layer over said silicon nitride layer having a predetermined first thickness; and
a silicon dioxide layer grown over said silicon layer, said silicon dioxide layer having a predetermined second thickness formed by exposing said silicon layer to a dry oxygen environment, said second thickness being proportionately related to said first thickness by a predetermined ratio controllable by a predetermined oxidation rate characteristics between said silicon material and dry oxygen.
